(19) United States
(12) Patent Application Publication
(10) Pub. No.: US 2024/0088462 A1
(43) Pub. Date: Mar. 14, 2024

(54) FORCED DISCHARGE FOR BATTERIES

(71) Applicant: Ascend Elements, Inc., Westborough, MA (US)

(72) Inventors: William D. Danielson, JR., Westborough, MA (US); Gregory Davis, Westborough, MA (US)

(21) Appl. No.: 18/244,745

(22) Filed: Sep. 11, 2023

Related U.S. Application Data
(60) Provisional application No. 63/404,986, filed on Sep. 9, 2022.

(51) Int. Cl. H01M 10/44; G01R 31/367

(52) U.S. Cl. CPC H01M 10/446; G01R 31/367

(57) ABSTRACT

A method for discharging end-of-life batteries prior to dismantling and recycling involves recovering residual stored electrical energy by draining the battery to a zero charge state, and reverse biasing the battery to bring the potential from a zero charge state of around 2.7 V to a zero or near zero energy state. The reverse bias inverts the normal usage polarity for inducing a reverse current flow, and continues based on formation of internal short circuits formed on the cathode current collector for rendering the battery with little to no energy storage for safe agitation and dismantling.

### RELATED APPLICATIONS

This patent application claims the benefit under 35 U.S.C. § 119(e) of U.S. Provisional Patent App. No. 63/404,986, filed Sep. 9, 2022, entitled “FORCED DISCHARGE FOR BATTERIES,” incorporated herein by reference in entirety.

### BACKGROUND

Li-ion batteries (LIBs) have been widely applied in recent decades, particularly with respect to electric vehicles (EV) and plug-in/hybrid electric vehicles (PHEV) which have been equipped with or directly powered by LIB s. LIB s have been widely used in portable electronics, electric vehicles, and grid storage as dominant power sources. LIBs offer substantial capabilities for energy storage, or density, and discharge capacity, and continue to retain residual electrical energy even after being deemed to have surpassed a useful service life of charge/discharge performance.

### SUMMARY

A method for discharging end-of-life batteries prior to dismantling and recycling involves recovering residual stored electrical energy by draining the battery to a zero state of charge, and reverse biasing the battery to bring the potential from the zero state of charge of about 2.7 V to a zero or near zero energy state. The reverse bias inverts the normal usage polarity, which is believed to form internal short circuits on the cathode current collector, rendering the battery with little to no energy storage for safe shredding and/or grinding.

Configurations herein are based, in part, on the observation that secondary (rechargeable) batteries typically degrade through normal charge and discharge cycles to a point of unusability. In the case of electric vehicles (EVs), these vehicles encounter range and speed limitations that are no longer within acceptable parameters and require a replacement battery. Unfortunately, end-of-life batteries often retain substantial energy storage and discharge capability even after they are deemed “dead” due to an inability to store and deliver charge (electrical energy) according to a sufficient performance criteria. Recycling processes which dismantle and grind/shred the physical battery containment and contents can trigger a sudden release of this residual energy, causing sparks, heat and fire risk. Connection of an electronic load can draw the residual energy but is extremely slow, and it can be difficult to assess completion.

Accordingly, configurations herein substantially overcome the shortcomings of end-of-life shredding and grinding of batteries by applying a reverse-bias overdischarge voltage to the battery or cells and computing a duration and/or quantum of energy to apply for rendering the battery at a zero energy state to have no residual voltage or current capacity, thereby mitigating the tendency for a rebound voltage to emerge after the reverse voltage bias is removed.

In further detail, forced discharge of Li-ion batteries from a recycling stream occurs for discharging the batteries to safe levels prior to recycling the batteries and recovering battery charge material. An amount of energy stored in a battery is computed from peak current and decay testing. Discharge and reverse bias logic determines a time and discharge rate for attaining a zero energy state based on the computed amount of energy. A reverse voltage is applied to terminals of the battery based on the determined time and discharge rate for inducing a reverse current flow and is continued for the determined time to attain the zero energy state.

### BRIEF DESCRIPTION OF THE DRAWINGS

The foregoing and other features will be apparent from the following description of particular embodiments disclosed herein, as illustrated in the accompanying drawings in which like reference characters refer to the same parts throughout the different views. The drawings are not necessarily to scale, emphasis instead being placed upon. illustrating the principles of the invention.

FIG. 1 is a context diagram of a forced or reverse-bias discharge configuration;

FIG. 2 is a schematic diagram of a device and operation for forced discharge as in FIG. 1; and

FIG. 3-5 show results of an example discharge as in FIGS. 1-2.

### DETAILED DESCRIPTION

A battery discharge method and apparatus renders batteries, such as Li-ion batteries, that are in a zero state of charge to attain a zero energy state prior to recycling of charge materials in the battery, which usually involves physical grinding and/or shredding for forming a granular mass of comingled battery particles, often referred to as “black mass.” The grinding process is not delicate and can be hazardous if residual electrical energy (“charge”) remains in the battery. Example configurations below demonstrate discharging a battery in a recycling stream by recovering usable electric energy for grid sourcing. Once usable energy has been extracted, defined by the battery attaining a zero state of charge, it still exhibits a voltage (potential difference), and a forced discharge process is used to bring the battery to a zero energy state.

Conventional approaches to battery discharge attempt to drain electrical energy from the battery by applying an external load and/or a simple short (low resistance connection) between the terminals. However, this approach is extremely time consuming and does not always result in a zero energy state. Furthermore, batteries have a tendency to “rebound,” or revert to a zero state of charge of around 2.7 volts once a load or short is removed, poses an ongoing risk of sparks and heat.

By comparison, in the present disclosure, application of a reverse biased voltage, overcomes these issues. It is believed that applying a reverse voltage to the battery terminals causes the formation of internal shorts (low or no resistance connections) by dissolution of the copper current collector to which the anode material is typically adhered. These internal shorts result in a battery with no stored energy or residual voltage, and thus causes no sparks or sudden release when crushed or shredded for recycling. Computation of the quantum (amount) of overdischarge energy to be delivered by the reverse biasing allows precise and efficient timing and delivery of the overdischarge energy called for to bring the battery to a state of zero energy storage. Conventional approaches do not assess or calculate a degree or duration of reverse biased current/voltage, nor describe formation of internal short circuits from dissolution or degradation of current collectors. Further, conventional approaches merely short or direct the residual load to resistive elements for heat dissipation and do not disclose receiving residual electrical energy for storage or redistribution back to the electric grid.

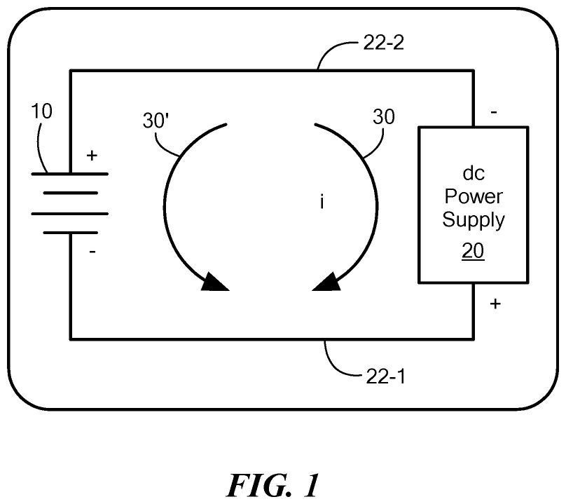

FIG. 1 is a context diagram of a forced or reverse-bias discharge configuration. Referring to FIG. 1, battery 10 has two electrical connections, 22-1 and 22-2, to the battery electrodes, which are the internal charge carrying members for battery energy. In normal discharge, where the battery powers a load such as a vehicle motor, electrons flow in a direction 30′. Specifically, electrical energy in the form of electrons flows from one terminal, or pole, of the battery, powers a load, and returns to the battery through the other terminal of an opposed polarity. Lithium ions within the battery complete the cycle as they pass across a separator internal to the battery.

In configurations herein, a reverse voltage source, such as DC power supply 20, causes a current flow 30, thereby driving additional current through the battery to cause a decrease in voltage to the point of a voltage reversal. The reverse voltage source is applied by connecting the higher potential of power supply 20 to the lower potential terminal of battery 10 and connecting the lower potential of the power supply to the higher potential battery terminal. Battery terminals are often labeled as positive (+) and negative (−), where the positive is at a higher potential, or voltage. Current flows from the positive high potential terminal to the negative low potential terminal. Somewhat paradoxically, electrons have a negative charge. So, the typical nomenclature often labels the negative terminal as the one from which the negatively charged electrons flow and the positive terminal as the one to which the electrons flow and from which the current flows. Regardless of polarity labels, the reverse voltage induces a current flow through the battery, thereby reversing the battery voltage.

Lithium-ion batteries usually cycle between 100% and 0% state of charge. However, a battery still has an open circuit voltage of ˜2.7 volts when at 0% state of charge (zero state of charge) and enough energy to create sparks and a fire risk when the battery is shredded during recycling operations.

Overdischarging the battery below 0% state of charge can cause dissolution of the copper current collector, which creates internal short circuits within the battery and dissipates the remaining battery energy as heat. It is believed that this process can be encouraged by using the forced discharge method described herein, wherein a reverse potential power supply is attached to the battery to accelerate the copper plating involved in creating the internal short circuits. Forced discharge is used in short circuit testing of batteries for assuring the battery can safely handle a short circuit.

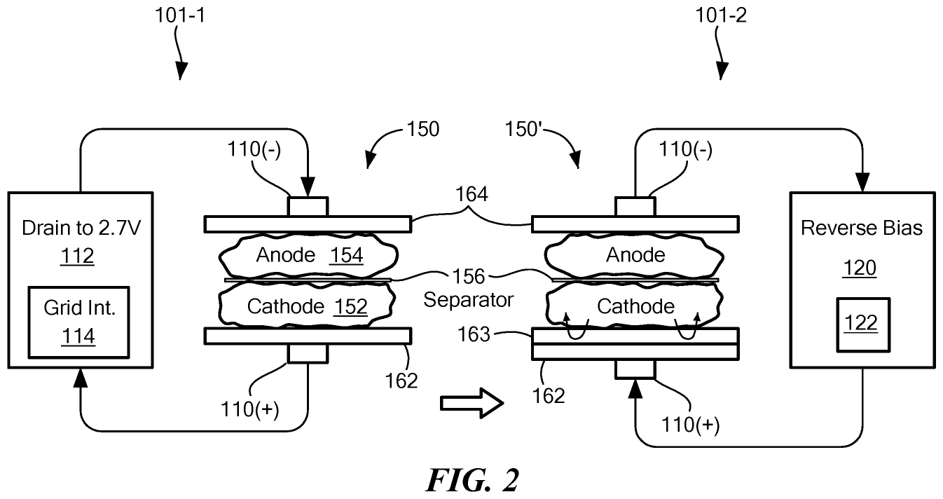

FIG. 2 is a schematic diagram of a device in various stages of operation for forced discharge as in FIG. 1. Referring to FIG. 2, a schematic diagram of a transition from zero state of charge 101-1 of Fig. to a zero energy state 101-2 is shown. The method for discharging batteries in a recycling stream includes engaging terminals 110(−) and 110(+) (110 generally) of battery 150 having a nonzero state of charge for receiving electrical energy stored in the battery. Terminal 110(+) is the cathode terminal associated with emanating current flow defining the higher potential (voltage) of in-use vehicle electrical delivery, while terminal 110(−) is the anode side defining the lower potential.

Reviewing the structure of battery 101-1 for recycling, cathode 152 contains metals, conductive particles, and binder adhered to current collector 162, which is typically aluminum. Metals can include nickel, manganese, cobalt, aluminum and others bound with lithium in a mixture that defines the battery chemistry and adhered with binder and conductive particles (typically carbon) to current collector 162. Current flow during discharge emanates from cathode terminal 110(+), and then powers a load before continuing to anode terminal 110(−), which includes anode 154, typically containing carbon or graphite, on anode current collector 164, which is often copper. Li ions pass through separator 156 between cathode 152 and anode 154, completing the electrical circuit.

A discharge load 112 drains residual voltage/current to a storage or grid interface 114 and detects when a potential difference between the terminals is substantially zero. This represents a low resistance connection for drawing residual electrical energy and continues until a state of zero state of charge is attained at approximately 2.5-2.7 volts.

Once a zero state of charge is achieved, referring to battery 101-2, a reverse bias 120 (such as a DC power supply) is engaged for applying a voltage to the terminals 110(+) and 110(−) for overdischarging the battery below 0 volts. This effectively forces a current or electron flow through the battery, driving the residual voltage below 2.7 towards 0.

It is significant to recognize the difference between a zero voltage and zero energy. Zero voltage refers to a time of zero potential between terminals 110, even though the charge material retains residual energy. Once the load/drain 112 is merely removed, the voltage rebounds to about 2.5-2.7V over a brief interval. Zero energy refers to a state in which there is no residual energy to rebound back to 2.5-2.7V, such as through the formation of internal shorts or electrical pathways. The reverse voltage is a reverse potential power supply defined by an inversion of voltage polarity of the battery during normal charging; in other words, a negative voltage relative to in-use polarity when charging a vehicle.

Reverse biasing logic 122 monitoring the reverse-bias electrical flow completes application of the reverse voltage based on determination of internal short circuits in the battery. The short circuit detector tracks degradation of the current collector 164 by closing (shorting) the battery terminals 110 and measuring a peak current and decay rate to compute a quantum of reverse bias energy to be delivered by the reverse bias circuit 120, neutralizing the overdischarged battery 101-2. The short circuit detector determines the amount of energy for delivery by the reverse voltage source to achieve a zero voltage and zero current capacity in the battery. The quantum or amount of energy is based on switching between open and closed loads on the battery and measuring a peak current and decay rate. Any suitable combination of voltage and current delivery over time may be employed for determining an optimal quantum of overdischarge energy for neutralizing the battery from further release of harmful or unexpected electrical energy.

Determination of residual charge includes briefly connecting the battery terminals (“shorting”) and measuring a peak current and the decay rate. The decay rate is used to calculate the total time needed to drain the battery (or module thereof) to a zero energy state. A prediction of energy needed by reverse discharge is performed by measuring the initial decay rate and recognizing the decay rate is slowing and asymptotically approaching 0. Trapezoidal Integration is used to calculate the Current-Time (I-T), and the Total Discharge Time is equal to the Area under Curve/Discharge Current Used:

∫I dt/Discharge Current=Time

Thus computing the amount of energy is based on an area defined by a graph of the measured peak current and an estimated asymptotic decay of the current based on the decay rate. In the example configuration, the internal short circuits are based on dissolution of the copper current collector 164 in contact with the anode material 154 in the battery 101. The reverse bias 120 effectively forces a current flow through battery 150′, inducing the internal short circuits from dissolution of the copper current collector, where reverse is relative to normal charge current flow during normal battery charging.

In general, batteries relegated to the recycling stream for discharge contain useable, recoverable charge in the form of electrical energy, and thus the discharge load receives electrical energy from a battery having a nonzero state of charge. Recovered energy is available from battery current transferred to an electrical grid for storage or transmission.

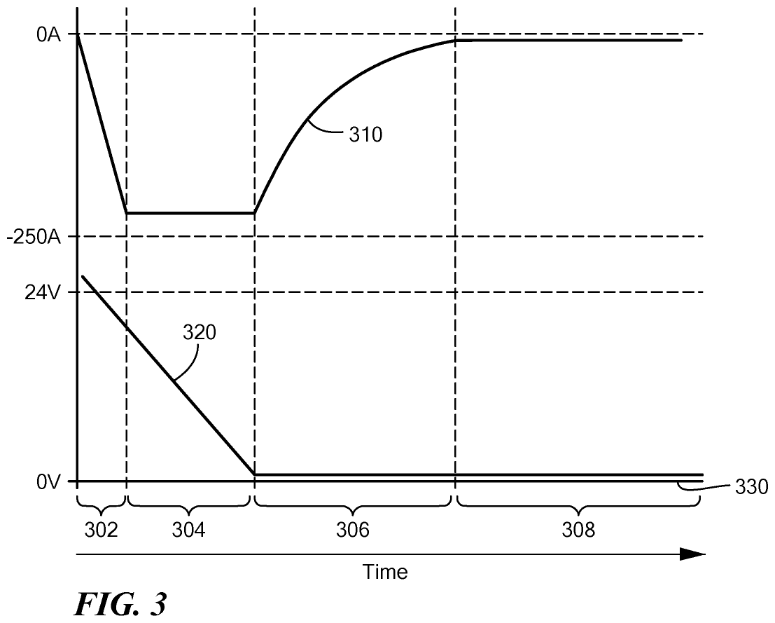

FIG. 3 is a graph of battery energy levels during an example discharge process. Referring to FIGS. 1-3, incoming batteries from a recycling stream have an unknown state of charge, but even when approaching an end of “service life,” the battery is likely to be above a zero state of charge state. As such, remaining electrical energy may be drawn off for grid supply or otherwise recovered. FIG. 3 shows concurrent timing progressions of voltage (line 320) and current flow (line 310) over time during the forced discharge process.

Application of the reverse voltage may occur at any time, preferably upon or just prior to achieving a zero charge state. The process may commence by receiving electrical energy from a battery having a nonzero state of charge as the reverse polarity power supply. Heat generation is mitigated by directing excess electric energy to grid or storage resources until the battery is exhausted to a zero state of charge. The reverse voltage commences at interval 302. As the computed reverse voltage is applied, the current (negative value relative to normal discharge load) rapidly attains a plateau, here at −240 amps. Voltage at the battery terminals rapidly falls to 0 through interval 304. Upon attaining a zero voltage, internal short circuits may commence, rendering the battery benign. Conventional approaches attach or weld a conductor between the opposed terminals for “shorting” the battery and ensuring a benign state. The reverse voltage achieves this benign state more efficiently. At interval 306, the reverse biasing continues as voltage remains near 0 and the needed current draw diminishes. An iterative reverse voltage may be employed as a refinement.

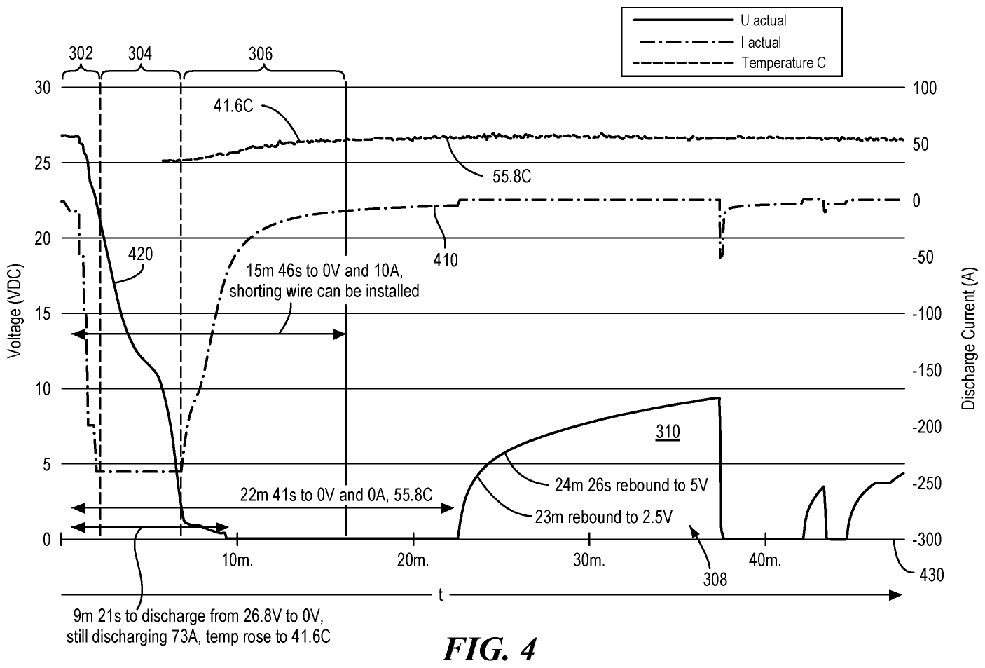

FIG. 4 shows results of an example discharge as in FIGS. 1-3, along with timing for accelerated discharge while managing generated heat. In FIG. 4, line 410 shows the current (amps) flowing into the battery, and line 420 shows the corresponding voltage, both against a horizontal time axis 430. As in FIG. 3, interval 302 marks the application of reverse bias voltage and the corresponding current increase and voltage reduction to 0. Interval 304 shows constant current while the battery voltage continues towards 0. Interval 306 denotes a constant voltage as the battery current drains, rendering the battery harmless, similar to external short circuits used in conventional approaches. An iterative step may occur, shown as a voltage increase at 310, where batteries persist with a non-zero energy state even following the computed discharge time. Successive iterations may occur to ensure residual voltage is brought to safe levels and preferably completely nullified.

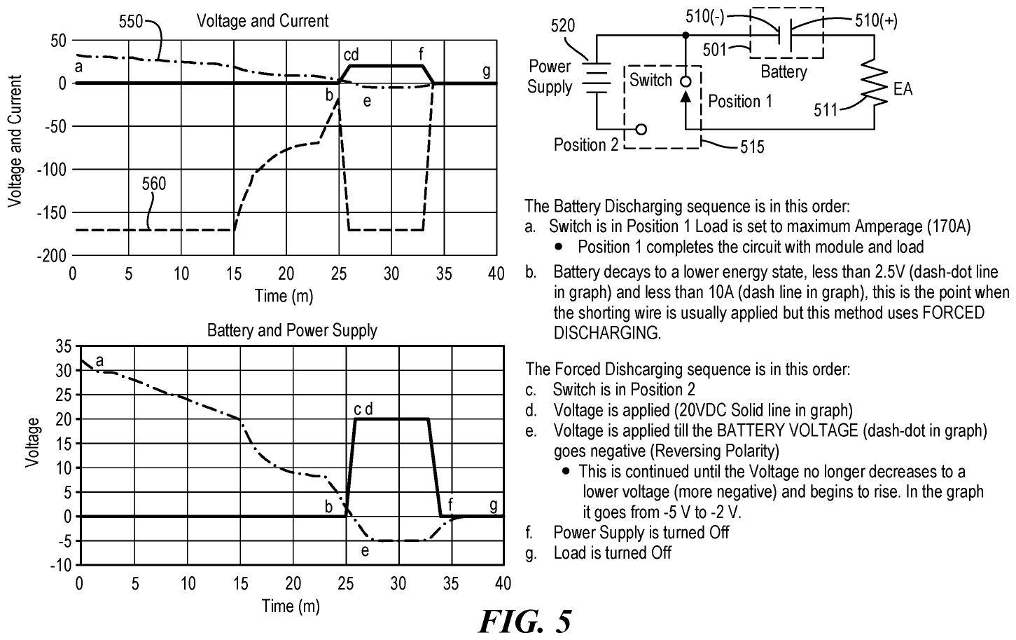

Another view of this process and device is shown in FIG. 5. Battery 501 includes anode terminal 510(−) and cathode terminal 510(+). The cathode terminal is electrically connected to load 511 while the anode terminal is electrically connected to power supply 520. The load and power supply are separated by switch 515, which alternately connects and disconnects the battery from the power supply.

As shown, when switch 520 is in Position 1, a circuit is completed between the load and the battery. In this position, the load drains the battery to a lower energy state, preferably a zero state of charge. This is described in FIG. 5, with voltage 550 gradually decaying over time to about 2.5-2.7 volts (noted as time “b”). In addition, current 560, produced by the battery, is also significantly reduced but is not eliminated. Thus, as discussed above, the battery is not yet devoid of energy (i.e., is not yet at a zero energy state).

At this stage, in conventional processes, a shorting wire is typically applied across the battery terminals in order to cause the remaining energy in the battery to dissipate. However, this process takes considerable time, and it can be difficult to know when a zero energy state is actually achieved, which poses the risk of voltage rebound, essentially reenergizing the battery. Instead, as shown in FIG. 5, a forced discharge approach is used.

Specifically, when a zero state of charge is reached, switch 515 is moved to Position 2, thereby connecting battery 501 and load 511 to power supply 520. FIG. 5 shows the corresponding changes in current and voltage that result from this forced discharge process. Thus, when the switch is repositioned at time “b”, a sharp rise in voltage to time “c” results along with a large increase in current from the power supply (shown as a large decrease on a negative amperage scale). This voltage is maintained until battery 501 attains a negative voltage value that does not change, at time “e” (i.e., until the polarity of the battery is reversed). This value may be, for example, −5V. The forced discharge is continued until the voltage begins to increase, indicating that the battery can no longer hold a charge. Power supply 520 is then turned off, such as at time “f” and having a voltage of −2V, followed by load 511. If desired, a shorting wire can also be applied to the battery terminals at this point.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. In a recycling stream of Li-ion batteries, a method for discharging a Li-ion battery prior to shredding or grinding and recovering battery charge materials from the battery, comprising
computing an amount of energy stored in the battery, the battery having a zero state of charge;
determining a time and discharge rate for the battery attaining a zero energy state based on the computed amount of energy;
applying an external power supply to cause a reverse voltage to terminals of the battery based on the determined time and discharge rate for inducing a reverse current flow; and
continuing the reverse voltage for the determined time to attain the zero energy state.

2. The method of claim 1 wherein applying the reverse voltage includes connecting a higher potential of the voltage source to a lower potential battery terminal and connecting a lower potential of the voltage source to a higher potential battery terminal.

3. The method of claim 1 wherein computing the amount of energy stored in the battery includes:
measuring a peak current and a decay rate between terminals of the battery; and
computing the amount of energy based on an area defined by a graph of the measured peak current and an estimated asymptotic decay of the current based on the decay rate.

4. The method of claim 1 wherein computing the determined time and reverse voltage further comprises:
connecting a sensory device between terminals of the battery for a duration of a test interval;
measuring a peak current and a decay rate of a current received by the sensory device during the test interval; and
computing a decay function based on the peak current and an estimated decay over time exceeding the test interval.

5. The method of claim 1 wherein the internal short circuits result from dissolution of copper current collectors in contact with the cathode material in the battery.

6. The method of claim 5 further comprising inducing copper plating from the reverse voltage for defining a conduction path between the battery terminals.

7. The method of claim 1 further comprising:
receiving electrical energy from a battery having a nonzero state of charge;
applying the reverse voltage to the battery upon attaining a zero state of charge; and
continuing application of the reverse voltage for achieving a zero energy state.

8. A device for a discharging Li-ion battery to safe levels prior to dismantling and recovering battery charge material, comprising:
a pair of connections to the battery, each connection to a respective opposed electrode;
a power supply for supplying a voltage; and
reverse biasing logic, the reverse biasing logic configured to apply a reverse bias voltage from the power supply to the pair of connections for causing a zero energy state in the battery.

9. The device of claim 8 further comprising a grid connection, the grid connection responsive to the reverse biasing logic for receiving energy from a residual charge, the residual charge defined by energy delivered as the battery depletes to a zero charge state.

10. The device of claim 8 further comprising a discharge switch, the discharge switch responsive to the reverse biasing logic for switching the pair of connections to the reverse bias voltage when the battery attains a zero charge state.

11. The device of claim 8 wherein the reverse biasing logic is operable to:
detect a peak voltage from the pair of connections;
detect a decay rate indicative of a reduction in voltage over time; and
compute a time and discharge rate for the battery to attain a zero energy state.

12. The device of claim 8 wherein the reverse biasing logic is operable to:
force a reverse current flow to the battery for inducing internal short circuits from dissolution of a copper current collector; and
terminate the reverse current flow upon the battery attaining a zero energy state.

13. The device of claim 11 wherein the reverse biasing logic is configured to direct the voltage supply to apply the reverse bias voltage for the computed time and discharge rate, and result in internal short circuits in the battery from dissolution of copper current collectors in contact with the cathode material in the battery.

14. The device of claim 1 wherein the reverse bias voltage is a reverse potential power supply defined by an inversion of voltage polarity of the battery during normal usage.

15. A method for discharging batteries in a Li-ion battery recycling stream, comprising:
engaging terminals on a battery having a nonzero state of charge for receiving electrical energy stored in the battery;
detecting when a potential difference between the terminals is substantially zero;
computing an amount of energy to apply via a reverse voltage to the terminals for neutralizing residual energy storage and discharge capacity in the battery; and
completing application of the reverse voltage based on determination of internal short circuits in the battery.

16. The device of claim 15 further comprising:
applying a reverse voltage to the terminals for overdischarging the battery below a zero state of charge; and
continuing the application of the reverse voltage until a zero energy state is attained in the battery.

17. The method of claim 15 further comprising forcing a reverse current flow to the battery for inducing internal short circuits from dissolution of a copper current collector.

18. The method of claim 17 wherein the internal short circuits are based on dissolution of copper current collectors in contact with the cathode material in the battery.

19. The method of claim 15 further comprising determining an amount of energy for delivery by the reverse voltage for achieving a zero energy state in the battery.

20. The method of claim 15 further comprising determining the amount of energy based on iterative opening and closing a circuit with the battery for determining a peak current and a decay rate.
